(19) United States
(12) Patent Application Publication
(10) Pub. No.: US 2024/0429114 A1
(43) Pub. Date: Dec. 26, 2024

(54) SEMICONDUCTOR DEVICE

(71) Applicant: Kioxia Corporation, Tokyo (JP)

(72) Inventor: Yoshiharu OKADA, Yokkaichi (JP)

(73) Assignee: Kioxia Corporation, Tokyo (JP)

(21) Appl. No.: 18/750,175

(22) Filed: Jun. 21, 2024

(30) Foreign Application Priority Data
Jun. 22, 2023 (JP) 2023-102518

(51) Int. Cl. H01L 23/31; H01L 21/304; H01L 25/00; H01L 25/065; H01L 25/16

(52) U.S. Cl. CPC H01L 23/3114; H01L 21/304; H01L 25/0657; H01L 25/16; H01L 25/50; H01L 2225/06506; H01L 2225/06562

(57) ABSTRACT

A semiconductor device including a first semiconductor chip that has a first surface including a first region and a second region adjacent to the first region; a second semiconductor chip provided on the first region; and resin provided on the second region and adjoining the second semiconductor chip, wherein at least a part of an interface between the first semiconductor chip and the resin has recesses and protrusions.

### CROSS-REFERENCE TO RELATED APPLICATION

This application is based upon and claims the benefit of priority from Japanese Patent Application No. 2023-102518, filed Jun. 22, 2023, the entire contents of which are incorporated herein by reference.

### FIELD

Embodiments described herein relate generally to a semiconductor device.

### BACKGROUND

In some semiconductor devices, semiconductor elements are sealed with a molding resin.

For example, if adhesion between the molding resin and the semiconductor element is poor, the molding resin may be detached from the semiconductor element.

An object of the present disclosure is to provide a semiconductor device, in which resin can be prevented from being detached from a semiconductor chip.

### BRIEF DESCRIPTION OF THE DRAWINGS

FIG. 1 is a perspective view of a storage device according to a first embodiment.

FIG. 2 is a schematic plan view when a semiconductor device according to the first embodiment is viewed from above.

FIG. 3 is a sectional view along a cutting-plane line III-III indicated in FIG. 2.

FIG. 4 is a sectional view with an enlarged hole portion along the cutting-plane line III-III indicated in FIG. 2.

FIG. 5 is a sectional view with an enlarged first variation of the hole portion along the cutting-plane line III-III indicated in FIG. 2.

FIG. 6 is a sectional view with an enlarged second variation of the hole portion along the cutting-plane line III-III indicated in FIG. 2.

FIG. 7 is a plan view when a section of a protruding portion, which is taken in parallel to an XY-plane, is viewed from above.

FIG. 8 is a plan view when a section of a protruding portion, which is taken in parallel to an XY-plane, is viewed from above.

FIG. 9 is a plan view when a section of a protruding portion, which is taken in parallel to an XY-plane, is viewed from above.

FIG. 10 is a plan view when a section of a protruding portion, which is taken in parallel to an XY-plane, is viewed from above.

FIG. 11 is a plan view when a section of a unit protruding portion, which is taken in parallel to an XY-plane, is viewed from above.

FIG. 12 is a plan view when a section of a unit protruding portion, which is taken in parallel to an XY-plane, is viewed from above.

FIG. 13 is a plan view when a section of a unit protruding portion, which is taken in parallel to an XY-plane, is viewed from above.

FIG. 14 is a plan view when a section of a unit protruding portion, which is taken in parallel to an XY-plane, is viewed from above.

FIG. 15 is a schematic view illustrating a manufacturing process of the semiconductor device according to the first embodiment.

FIG. 16 is a schematic view illustrating a manufacturing process of the semiconductor device according to the first embodiment.

FIG. 17 is a schematic view illustrating a manufacturing process of the semiconductor device according to the first embodiment.

FIG. 18 is a schematic view illustrating a manufacturing process of the semiconductor device according to the first embodiment.

FIG. 19 is a schematic view illustrating a manufacturing process of the semiconductor device according to the first embodiment.

FIG. 20 is a schematic view illustrating a manufacturing process of the semiconductor device according to the first embodiment.

FIG. 21 is a schematic view illustrating a manufacturing process of the semiconductor device according to the first embodiment.

FIG. 22 is a schematic view illustrating a manufacturing process of the semiconductor device according to the first embodiment.

FIG. 23 is a schematic view illustrating a manufacturing process of the semiconductor device according to the first embodiment.

FIG. 24 is a schematic view illustrating a manufacturing process of the semiconductor device according to the first embodiment.

FIG. 25 is a schematic view illustrating a manufacturing process of the semiconductor device according to the first embodiment.

FIG. 26 is a schematic view illustrating a manufacturing process of the semiconductor device according to the first embodiment.

FIG. 27 is a schematic view illustrating a manufacturing process of the semiconductor device according to the first embodiment.

FIG. 28 is a schematic view illustrating a manufacturing process of the semiconductor device according to the first embodiment.

FIG. 29 is a schematic view illustrating a manufacturing process of the semiconductor device according to the first embodiment.

FIG. 30 is a schematic view illustrating a manufacturing process of the semiconductor device according to the first embodiment.

FIG. 31 is a schematic view illustrating a manufacturing process of the semiconductor device according to the first embodiment.

FIG. 32 is a schematic view illustrating a manufacturing process of the semiconductor device according to the first embodiment.

FIG. 33 is a schematic section for describing an example structure of a semiconductor device according to a second embodiment, illustrating a sectional view in parallel to a YZ-plane.

FIG. 34 is a schematic view illustrating a manufacturing process of the semiconductor device according to the second embodiment.

FIG. 35 is a schematic view illustrating a manufacturing process of the semiconductor device according to the second embodiment.

FIG. 36 is a schematic view illustrating a manufacturing process of the semiconductor device according to the second embodiment.

FIG. 37 is a schematic view illustrating a manufacturing process of the semiconductor device according to the second embodiment.

FIG. 38 is a schematic section for describing an example structure of a semiconductor device according to a third embodiment, illustrating a sectional view in parallel to a YZ-plane.

FIG. 39 is a schematic section for describing an example structure of a pad and a via according to a fourth embodiment, illustrating a sectional view in parallel to a YZ-plane.

FIG. 40 is a schematic section for describing an example structure of recess surfaces and a protruding portion according to fourth embodiment, illustrating a sectional view in parallel to a YZ-plane.

### DETAILED DESCRIPTION

Various embodiments will be described hereinafter with reference to the accompanying drawings.

In general, according to one embodiment, a semiconductor device comprises a first semiconductor chip that has a first surface including a first region and a second region adjacent to the first region, a second semiconductor chip provided on the first region, and resin provided on the second region and adjoining the second semiconductor chip, wherein at least a part of an interface between the first semiconductor chip and the resin has recesses and protrusions.

The embodiments will now be described with reference to attached drawings. For ease of understanding of the description, in the drawings, similar components will have a similar reference sign if possible and any redundant description will not be repeated.

In the drawings, X-, Y-, and Z-axes may be indicated. The X-, Y-, and Z-axes form a right-handed three-dimensional Cartesian coordinate system. Hereinunder, the arrow direction on the X-axis may be referred to as an X-axis plus direction, and the direction opposite to the arrow may be referred to as an X-axis minus direction. The same applies to other axes. Note that a Z-axis plus direction and a Z-axis minus direction may also be referred to as “above” and “below” respectively. Planes perpendicular to the X-axis, the Y-axis, and the Z-axis may be referred to as a YZ-plane, a ZX-plane, and an XY-plane, respectively. A Z-axis direction may be referred to as “up-down direction”. The terms “above”, “below”, and “up-down direction” are terms for indicating a relative positional relationship in the drawings only, and not terms for defining orientations relative to the vertical direction.

Unless otherwise specifically stated in particular, dimensions or the like of components indicated in the drawings may be indicated differently than actual dimensions for ease of understanding of the description.

In the specification, “connection” includes not only a physical connection but also an electrical connection, and includes, unless otherwise specified in particular, not only a direct connection, but also an indirect connection in which the connection is made via other objects.

In the specification, “formed above” includes not only when a subject is formed in contact with an object above, but also when a subject is formed above via other objects unless otherwise specified in particular. The same applies to cases such as “formed below”.

### First Embodiment

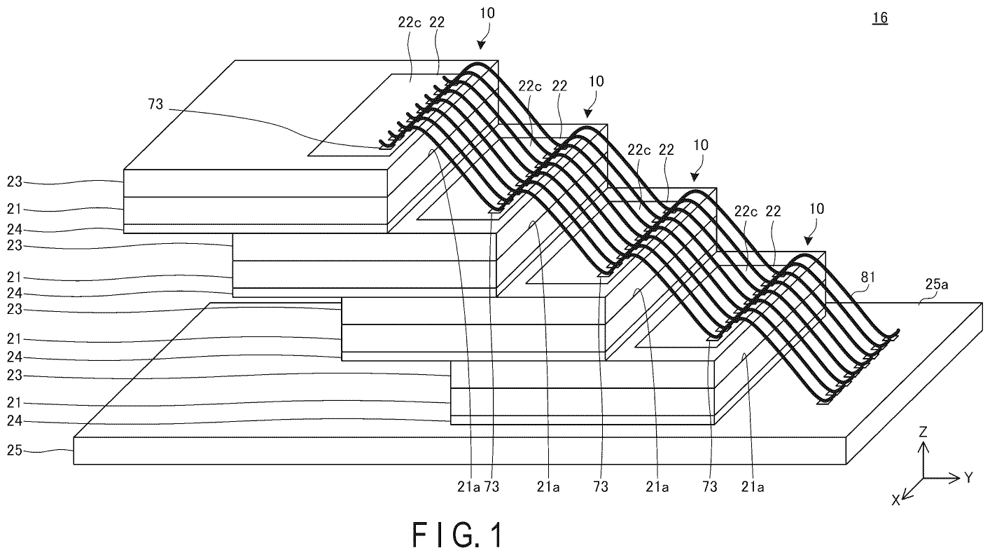

A configuration of the semiconductor device according to the first embodiment will now be described. FIG. 1 is a perspective view of a storage device according to the first embodiment. As illustrated in FIG. 1, a storage device 16 includes four semiconductor devices 10 and a wiring substrate 25. The storage device 16 may include 3 or less or 5 or more semiconductor devices 10.

The four semiconductor devices 10 are stacked stepwise on top of another when viewed from above such that second semiconductor chips 22 are exposed. The semiconductor device 10 located above and the semiconductor device 10 located below are adhered with a die-attach film 24. The lowermost semiconductor device 10 is adhered to an upper surface 25a of the wiring substrate 25 with a die-attach film 24.

The four semiconductor devices 10 and the wiring substrate 25 are electrically connected through bonding wires 81.

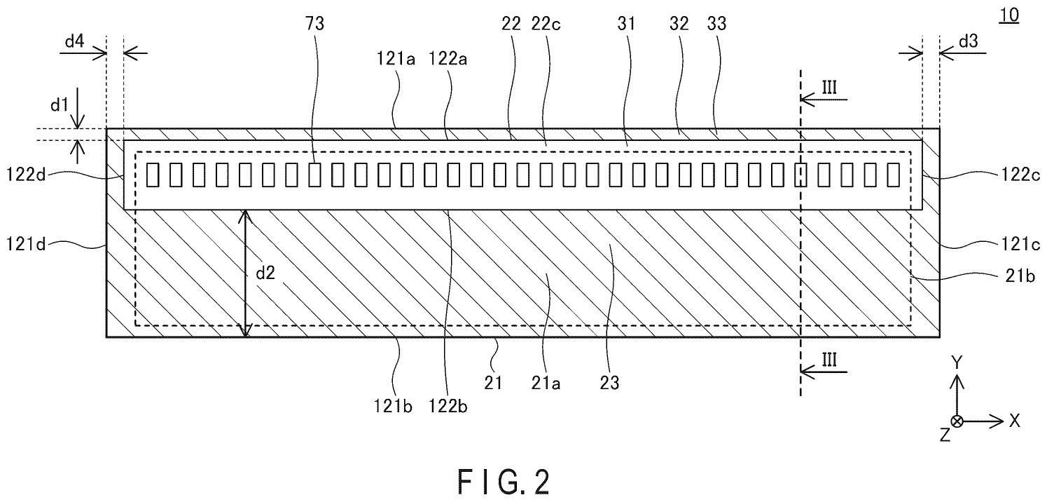

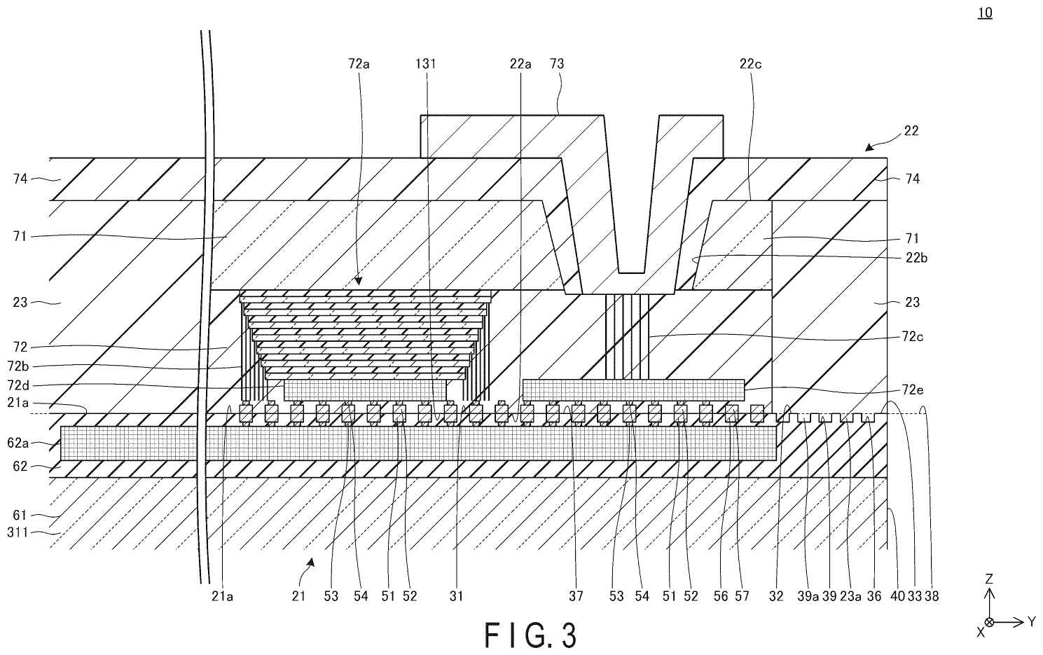

FIG. 2 is a schematic plan view when the semiconductor device according to the first embodiment is viewed from above. FIG. 3 is a sectional view along the cutting-plane line III-III indicated in FIG. 2.

As illustrated in FIGS. 2 and 3, the semiconductor device 10 includes a first semiconductor chip 21, a second semiconductor chip 22, and a sealing resin 23.

The first semiconductor chip 21 has a surface 21a (an example of “first surface”) above. The surface 21a is substantially in parallel to the XY-plane and is rectangular when viewed from above.

The surface 21a includes a first region 31 and a second region 32 adjacent to the first region 31. The second semiconductor chip 22 is provided on the first region 31. In the embodiment, the entire circumference of the first region 31 adjoins the second region 32. In other words, the first region 31 is surrounded by the second region 32. In an alternative configuration, only a part of the entire circumference of the first region 31 may adjoin the second region 32.

When the surface 21a is viewed in plan view along a direction perpendicular to the surface 21a (hereinafter, may be referred to as “when viewed from above in plan view”), the first semiconductor chip 21 has a side 121a (an example of “first side”) and a side 121b (an example of “second side”) that are opposite to each other, and sides 121c and 121d that are opposite to each other.

In the embodiment, the sides 121a and 121b are long sides substantially in parallel to the X-axis and located in the Y-axis plus direction and the Y-axis minus direction, respectively. The sides 121c and 121d are short sides substantially in parallel to the Y-axis and located in the X-axis plus direction and the X-axis minus direction, respectively. Alternatively, the surface 21a may be square.

When viewed from above in plan view, the second semiconductor chip 22 has sides 122a and 122b that are opposite to each other and sides 122c and 122d that are opposite to each other.

In the embodiment, the sides 122a and 122b are long sides substantially in parallel to the X-axis and located in the Y-axis plus direction and in the Y-axis minus direction, respectively. The sides 122c and 122d are short sides substantially in parallel to the Y-axis and located in the X-axis plus direction and the X-axis minus direction, respectively. Alternatively, the first region 31 may be square.

In other words, when viewed from above in plan view, the first region 31 has a long rectangular shape in the X-axis direction, and completely overlaps the second semiconductor chip 22. The second region 32 is a region excluding a rectangular defined by an outer shape of the first region 31, that is, the second semiconductor chip 22 from a rectangular defined by an outer shape of the first semiconductor chip 21, when viewed from above in plan view.

The first region 31 is located nearer to the side 121a than the side 121b. Specifically, a distance d1 between the side 121a of the first semiconductor chip 21 and the side 122a of the second semiconductor chip 22 is smaller than a distance d2 between the side 121b of the first semiconductor chip 21 and the side 122b of the second semiconductor chip 22.

A distance d3 between the side 121c of the first semiconductor chip 21 and the side 122c of the second semiconductor chip 22 is smaller than the distance d2. A distance d4 between the side 121d of the first semiconductor chip 21 and the side 122d of the second semiconductor chip 22 is smaller than the distance d2. The distances d3 and d4 are, for example, substantially the same.

The sealing resin 23 is provided on the second region 32 and adjoins the second semiconductor chip 22. When viewed from above in plan view, the entirety of the second semiconductor chip 22 is exposed from the sealing resin 23.

Specifically, the sealing resin 23 is, for example, epoxy resin. When viewed from above in plan view, the second region 32 is covered with the sealing resin 23. Four surfaces perpendicular to the XY-plane, that is, side surfaces of the second semiconductor chip 22 adjoin the sealing resin 23.

On the other hand, the entirety of an upper surface 22c (an example of “top surface”) of the second semiconductor chip 22 is exposed from the sealing resin 23. In an alternative configuration, when viewed from above in plan view, only a part of the surface 22c of the second semiconductor chip 22 may be exposed from the sealing resin 23.

The surface 22c of the second semiconductor chip 22 is provided with a plurality of bonding pads 73 arranged in line and substantially in parallel to the X-axis direction. The bonding wires 81 are connected to the bonding pads 73.

The first semiconductor chip 21 includes a semiconductor layer 61, an insulating layer 62, a plurality of pads 51 (an example of “first pad”), and a plurality of dummy pads 56 (an example of “first pad”).

The semiconductor layer 61 is, for example, of a CMOS (Complementary Metal Oxide Semiconductor). An upper surface of the semiconductor layer 61 includes a circuit-formed region 21b in which a CMOS circuit is formed (see FIG. 2). For example, the insulating layer 62 that includes silicon and oxygen is provided above the semiconductor layer 61. In the embodiment, the surface 21a is an upper surface of the insulating layer 62.

A plurality of pads 51 and a plurality of dummy pads 56 are formed in the first region 31 on the surface 21a. The pads 51 and dummy pads 56 include, for example, copper and are exposed from the insulating layer 62. The first region 31 is substantially flat.

A via 53 is connected below each of the pads 51. For example, the via 53 is electrically connected to the CMOS circuit in the circuit-formed region 21b through a wiring layer 62a formed on the insulating layer 62.

The second semiconductor chip 22 includes a semiconductor layer 71, an insulating layer 72, a plurality of pads 52 (an example of “second pad”), and a plurality of dummy pads 57 (an example of “second pad”).

The semiconductor layer 71 includes, for example, silicon. A hole portion 22b passing through the semiconductor layer 71 is formed in the second semiconductor chip 22. In place of the semiconductor layer 71, an insulating layer may be used. Such an insulating layer may be, for example, silicon oxide, silicon nitride, or the like.

The insulating layer 74 includes, for example, polyimide. The insulating layer 74 is provided on an upper surface of the semiconductor layer 71, an upper surface of the sealing resin 23, and side walls of the hole portion 22b. The bonding pads 73 include, for example, copper and are provided on an upper surface of the insulating layer 74 and a bottom surface of the hole portion 22b.

A lower surface of the semiconductor layer 71 is provided with a memory array 72a. The memory array 72a includes, for example, a plurality of stacked memory chips. An insulating layer 72 that covers the memory array 72a is provided below the semiconductor layer 71. The insulating layer 72 includes, for example, silicon and oxygen.

On a lower surface 22a (an example of “second surface”) of the insulating layer 72, a plurality of pads 52 and a plurality of dummy pads 57 are formed in a region 131 opposite to the first region 31. The pads 52 and dummy pads 57 include, for example, copper and are exposed from the insulating layer 72. The region 131 is substantially flat.

A via 54 is connected above each of the pads 52. For example, the memory array 72a is electrically connected to the via 54 through a via 72b and a wiring layer 72d formed in the insulating layer 72. For example, the bonding pads 73 are each electrically connected to the via 54 through a via 72c and a wiring layer 72e formed in the insulating layer 72.

The pads 51 and dummy pads 56 formed in the first semiconductor chip 21 and the pads 52 and dummy pads 57 formed in the second semiconductor chip 22 are joined, respectively, so that the first semiconductor chip 21 and the second semiconductor chip 22 are bonded.

Specifically, the pads 51/the dummy pads 56 and the pads 52/the dummy pads 57 are coupled respectively by annealing. For example, an attraction caused by hydrogen bond acts between the insulating layer 62 and the insulating layer 72.

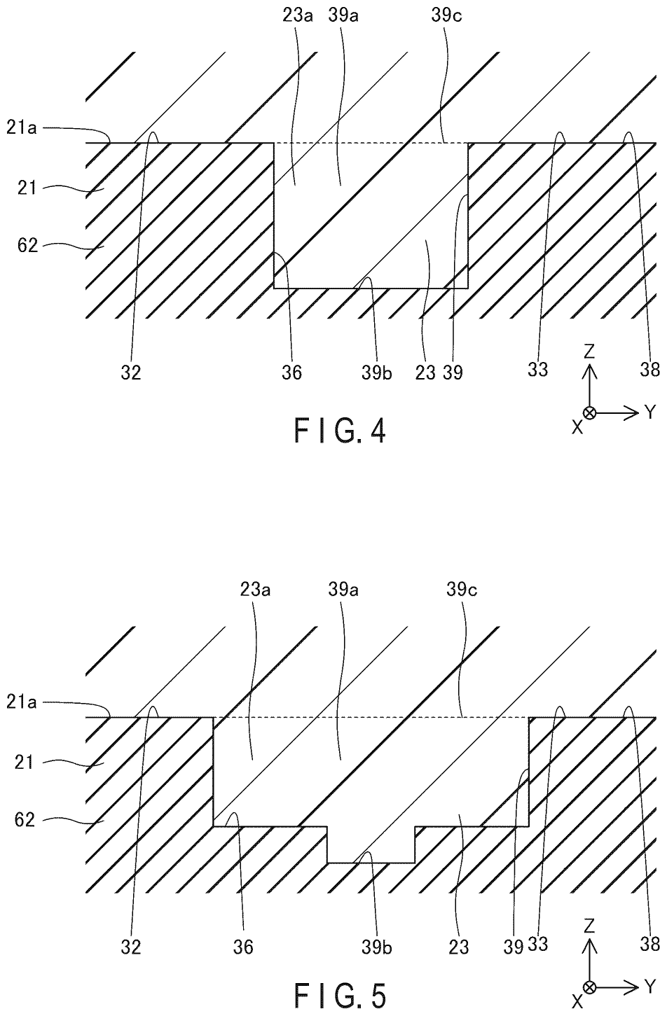

FIG. 4 is a sectional view with an enlarged hole portion along the cutting-plane line III-III indicated in FIG. 2. As illustrated in FIGS. 2 to 4, in the second region 32 on the surface 21a, at least a part of an interface 36 between the first semiconductor chip 21 and the sealing resin 23 has recesses and protrusions.

In the embodiment, the second region 32 includes a third region 33 located between the side 121a of the first semiconductor chip 21 and the first region 31 (see FIG. 2). The interface 36 in at least a part of the third region 33 has recesses and protrusions (see FIG. 3).

Specifically, as described above, since the first region 31 and the region 131 are substantially flat, a bonding plane 37 between the first semiconductor chip 21 and the second semiconductor chip 22 is also substantially flat. The third region 33 includes a plurality of recess surfaces 39 formed in a recessed manner below from the plane 38 that includes the bonding plane 37 between the first semiconductor chip 21 and the second semiconductor chip 22.

The sealing resin 23 has a protruding portion 23a that enters at least a part of a hole portion 39a, inner walls of which are the recess surfaces 39. In the embodiment, the protruding portion 23a enters the hole portion 39a entirely. In other words, the first semiconductor chip 21 has recesses and protrusions and the sealing resin 23 also has recesses and protrusions.

The shape of a section perpendicular to the protruding portion 23a and the surface 21a of the hole portion 39a, for example, a section along the cutting-plane line III-III (hereinafter, may be referred to as “first section”) and the shapes in the first section of the pads 51 and dummy pads 56 are a first shape. In the embodiment, the first shape is, for example, rectangular. In the hole portion 39a, inner walls of which are the recess surfaces 39, the shape of the bottom surface 39b and the shape of the opening 39c are substantially the same.

Although, in the embodiment, a configuration in which the shapes in the first section of the protruding portion 23a and the hole portion 39a are rectangular has been described, this is not a limitation. FIG. 5 is a sectional view with an enlarged first variation of the hole portion along the cutting-plane line III-III indicated in FIG. 2. As illustrated in FIG. 5, in the first variation of the hole portion 39a, the area of the opening 39c is larger than the area of the bottom surface 39b.

Specifically, the shapes in the first section of the first variation of the protruding portion 23a and the hole portion 39a is substantially the same as the shapes in the first section of the pad 51 and the via 53.

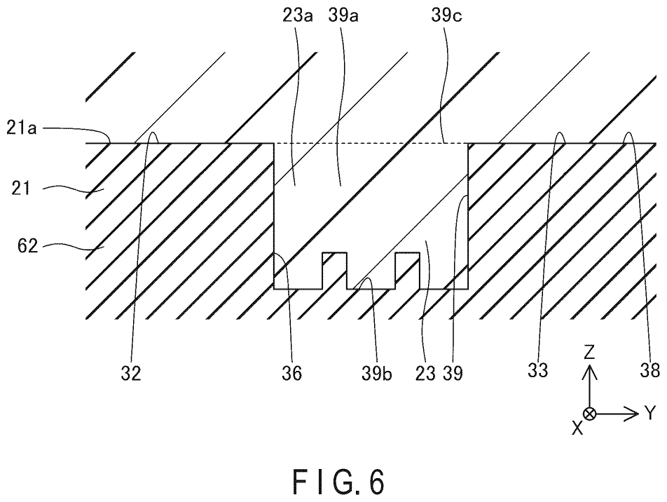

FIG. 6 is a sectional view with an enlarged second variation of the hole portion along the cutting-plane line III-III indicated in FIG. 2. As illustrated in FIG. 6, even though a plurality of vias 53 are provided below the pad 51, the shapes in the first section of the second variation of the protruding portion 23a and the hole portion 39a are substantially same as the shapes in the first section.

Without being limited to a configuration in which all the shapes in first section of a plurality of protruding portions 23a and hole portions 39a are the same, in an alternative configuration, a part or all of the shapes in the first section of a plurality of protruding portions 23a and hole portions 39a may be different. In the surface 21a in the first semiconductor chip 21, recesses and protrusions may be formed in all the second region 32 that is not joined with the second semiconductor chip 22. For example, recesses and protrusions (for example, hole portions similar to the hole portions 39a, although not illustrated) are formed in the second region 32 on the side in the Y-axis minus direction in FIG. 3. The sealing resin 23 is in contact with the hole portion.

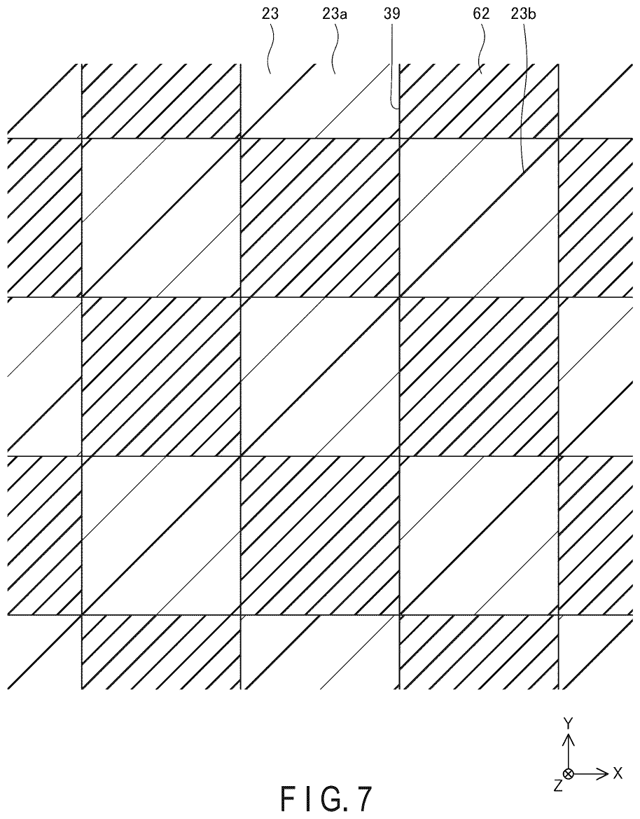

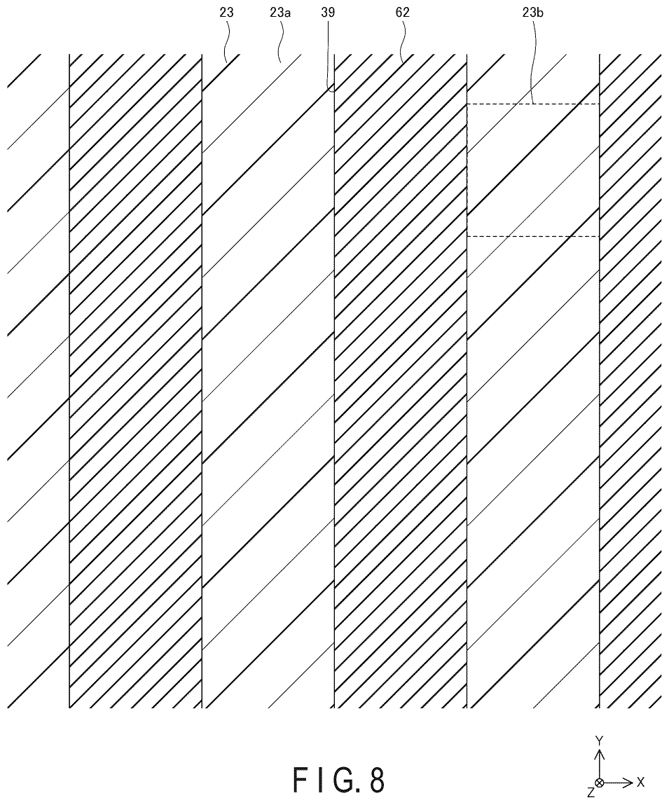

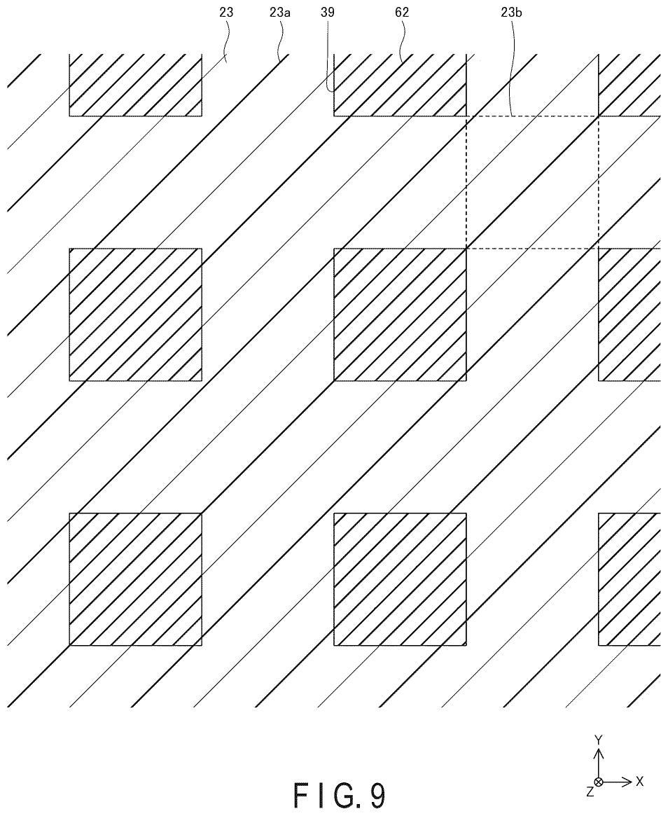

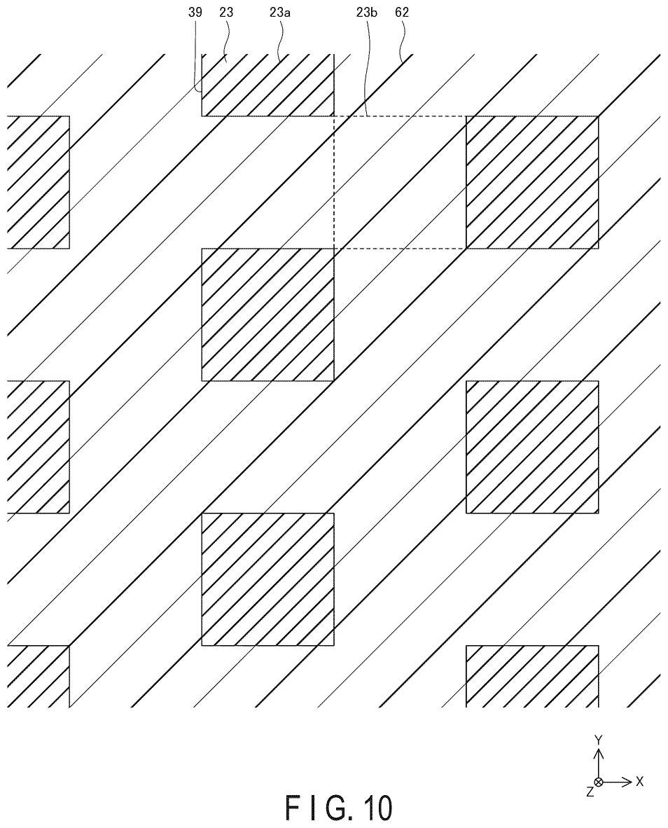

FIGS. 7 to 10 are plan views when a section of the protruding portion 23a, which is taken in parallel to an XY-plane, is viewed from above. As illustrated in FIG. 7, the recess surfaces 39 exhibit a geometrical pattern when viewed from above in plan view. Specifically, the recess surfaces 39 exhibit a grid pattern. To be specific, in the examples illustrated in FIG. 7, FIG. 8, FIG. 9, and FIG. 10, the recess surfaces 39 exhibit a checkered pattern, a strip pattern, a net pattern, and a staggered pattern, in each case. These grid patterns can be generated by arranging a plurality of unit protruding portions 23b, each of which is square in the shape of the section in parallel to the XY-plane, according to a predetermined rule.

In the examples illustrated in FIGS. 7 and 8, a part or all of a plurality of unit protruding portions 23b are separated to form a plurality of protruding portions 23a. In the examples illustrated in FIGS. 9 and 10, a plurality of unit protruding portions 23b are integrally continuous to form one protruding portion 23a. In the example illustrated in FIG. 7, the unit protruding portions 23b and the protruding portions 23a are the same as each other.

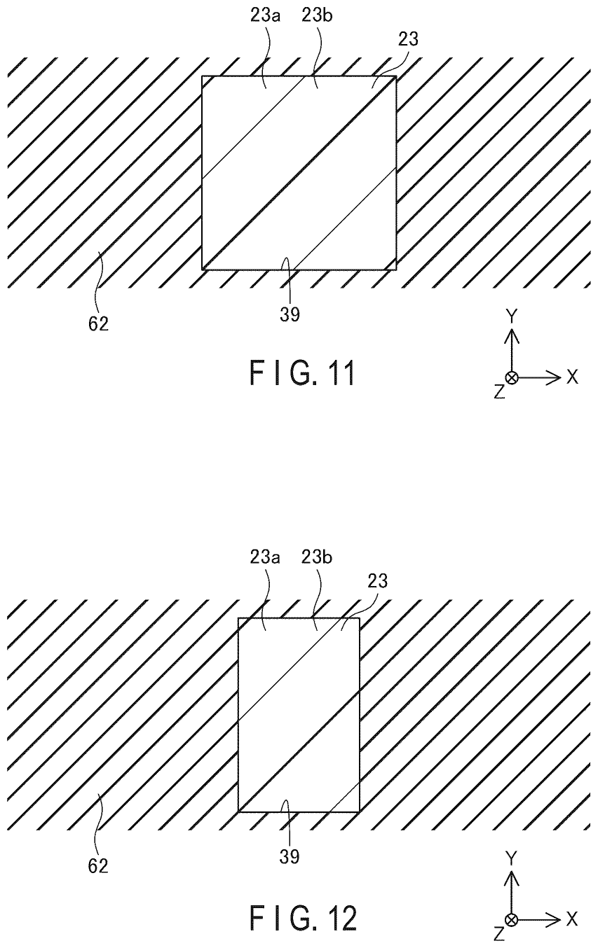

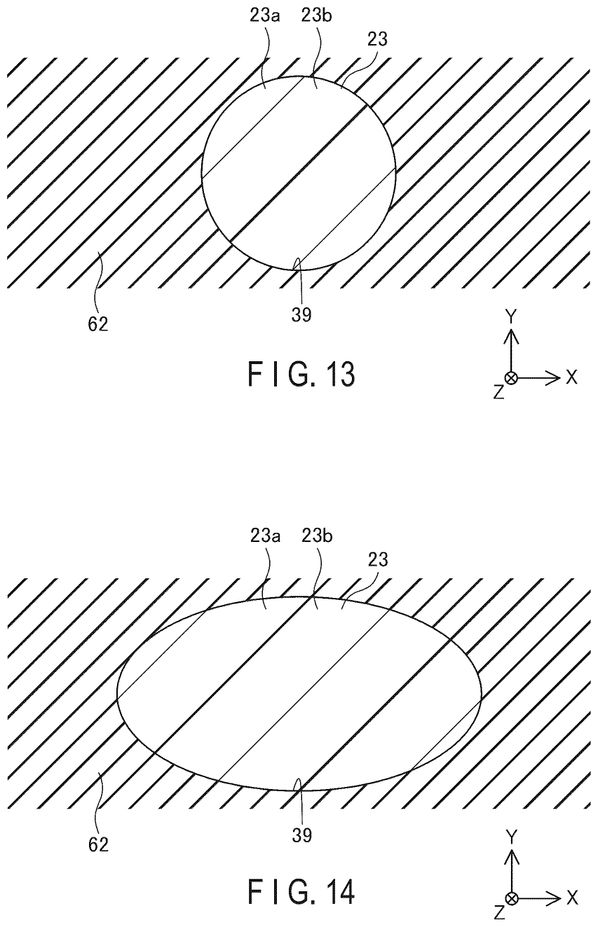

FIGS. 11 to 14 are plan views when a section of the unit protruding portion 23b, which is taken in parallel to an XY-plane, is viewed from above. FIGS. 11 to 14 illustrate examples of when the unit protruding portion 23b and the protruding portion 23a are the same as each other. As illustrated in FIGS. 11 to 14, when viewed from above in plan view, the recess surfaces 39 have square, oblong, circular, and elliptical outlines in each case.

### [Manufacturing Method of Semiconductor Device]

As an example of a manufacturing method of a semiconductor device according to the embodiment, a manufacturing method of a semiconductor device 10 will now be described.

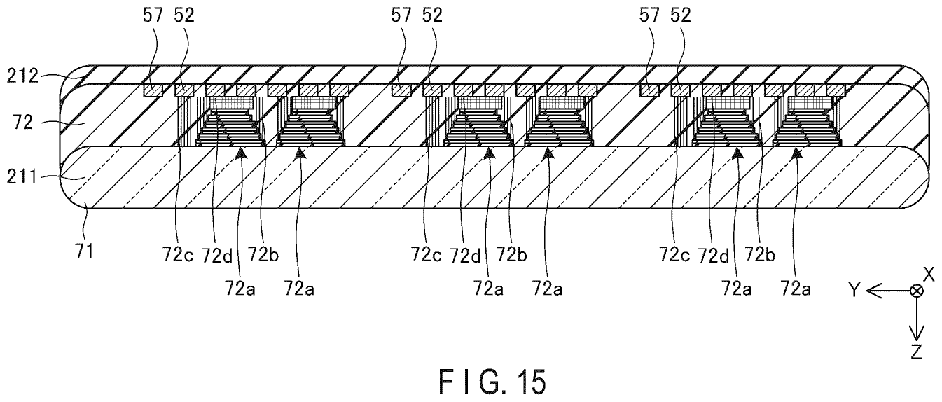

First, as illustrated in FIG. 15, insulating layers 72 that include memory arrays 72a, vias 72b and 72c, wiring layers 72d, pads 52, dummy pads 57, and the like are formed on an array wafer 211. A lower surface of the insulating layer 72 is then covered with, for example, an alkali-soluble protective film 212.

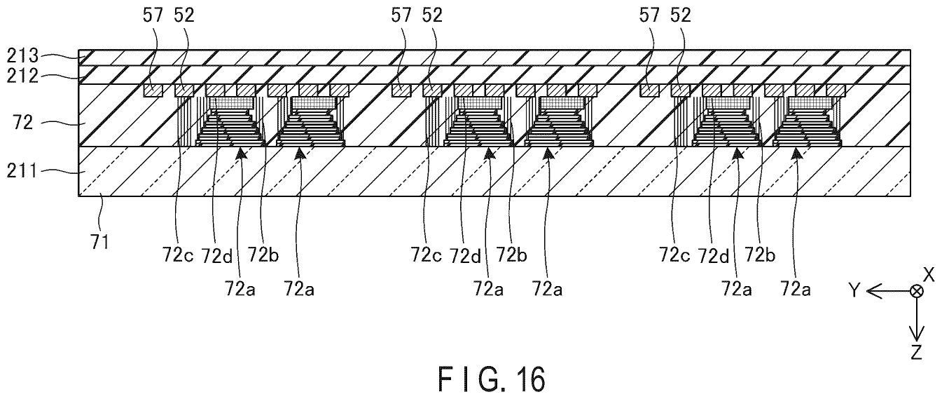

Next, as illustrated in FIG. 16, ends of the array wafer 211 in the Y-axis plus direction and the Y-axis minus direction are trimmed. Furthermore, a BG protective tape 213 is provided on a lower surface of the protective film 212.

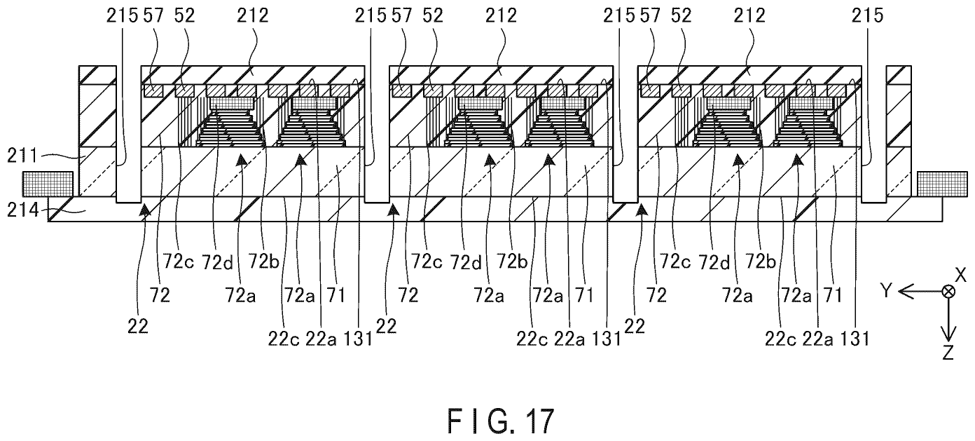

Next, as illustrated in FIG. 17, the array wafer 211 is placed on a dicing tape 214. After the BG protective tape 213 is removed from the array wafer 211, the array wafer 211 is cleaned. Then, the array wafer 211 is subjected to dicing from the upper surface so that groove portions 215 are formed. Those components formed on the array wafer 211 are divided into the second semiconductor chips 22 across the groove portions 215.

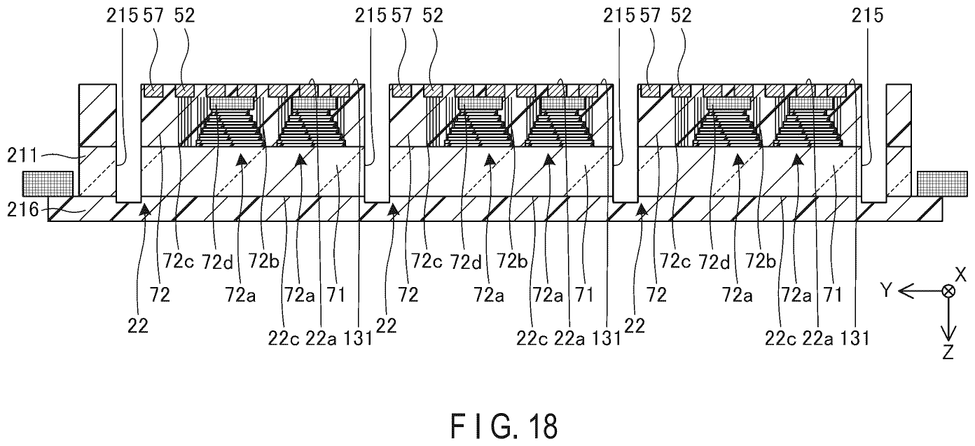

Next, as illustrated in FIG. 18, the second semiconductor chips 22 are transferred from the dicing tape 214 to a dicing tape 216. Then, the protective film 212 is removed. As a preprocessing for processing of bonding the second semiconductor chips 22 to the first semiconductor chips 21, the array wafer 211 is subjected to nitrogen plasma processing and rinsing.

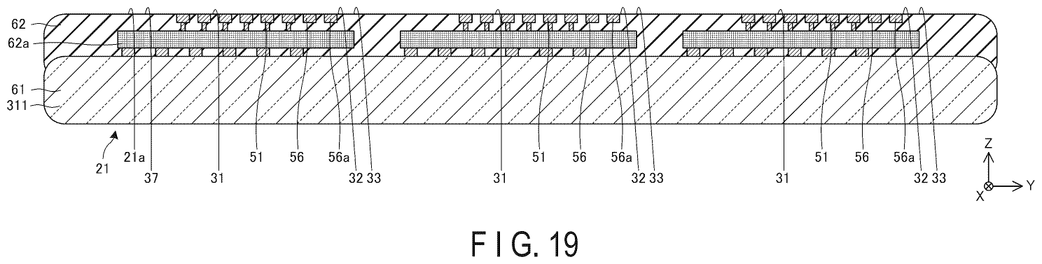

Next, as illustrated in FIG. 19, CMOS circuits are formed on an upper surface of a CMOS wafer 311. Then, the insulating layer 62 that include the pads 51, the dummy pads 56 and 56a, and the wiring layers 62a is formed on the upper surface of the CMOS wafer 311. Details of the dummy pads 56a will be described later.

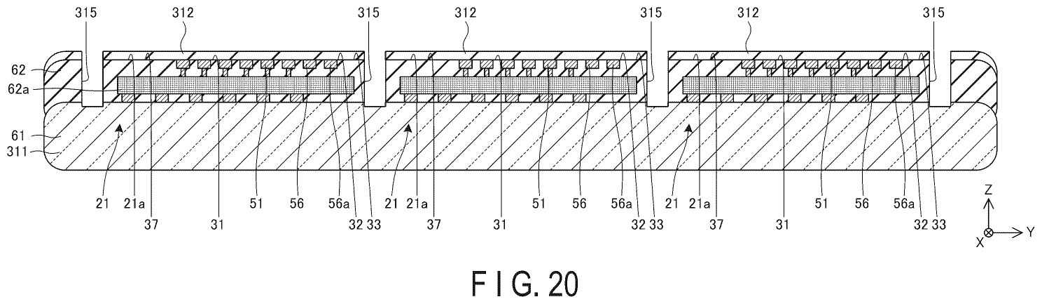

Next, as illustrated in FIG. 20, a protective film 312 is formed on the upper surface of the insulating layer 62. Then, in the CMOS wafer 311, groove portions 315 are formed by laser grooving process in which the upper surface is irradiated with laser. Those components formed on the CMOS wafer 311 are divided into the first semiconductor chips 21 across the groove portions 315.

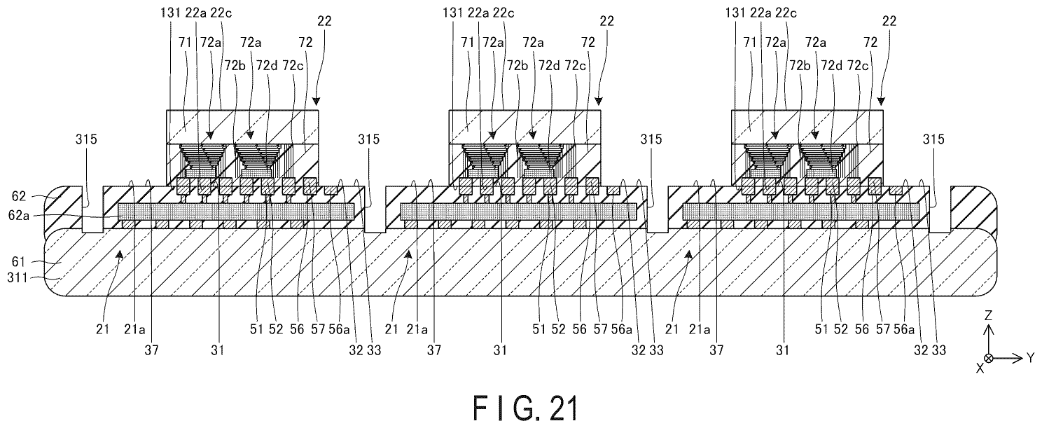

Next, as illustrated in FIG. 21, the protective film 312 is removed. As a preprocessing for processing of bonding the second semiconductor chip 22 to the first semiconductor chip 21, the CMOS wafer 311 is subjected to nitrogen plasma processing and rinsing. Then, the second semiconductor chip 22 is bonded to the first semiconductor chip 21. At this time, the dummy pads 56a among a plurality of dummy pads 56 are not bonded to the dummy pads 57 and left exposed. The CMOS wafer 311 is thereafter annealed.

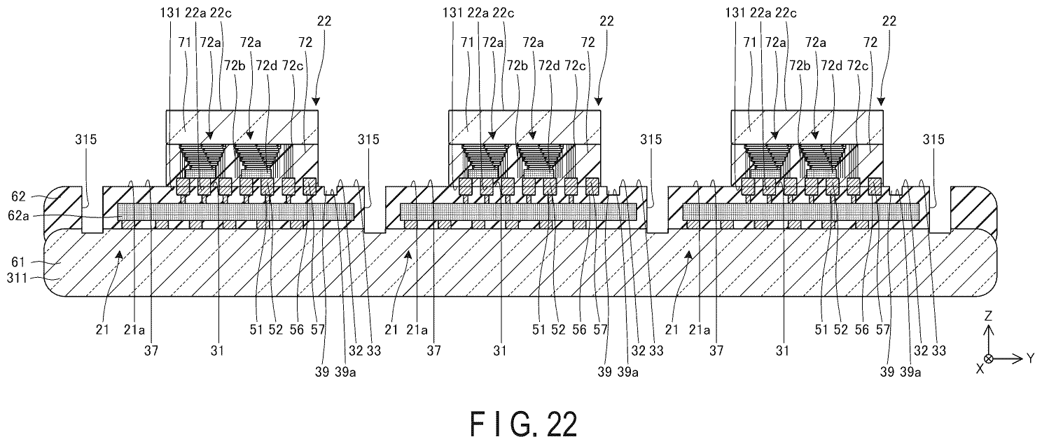

Next, as illustrated in FIG. 22, the CMOS wafer 311 is subjected to wet etching so that the dummy pads 56a are removed. This creates the recess surfaces 39 in a part of the surface 21a of the first semiconductor chip 21, forming the hole portions 39a. Here, for example, when there are the vias 53 formed below the dummy pads 56a, the vias 53 are also removed by wet etching along with the dummy pads 56a.

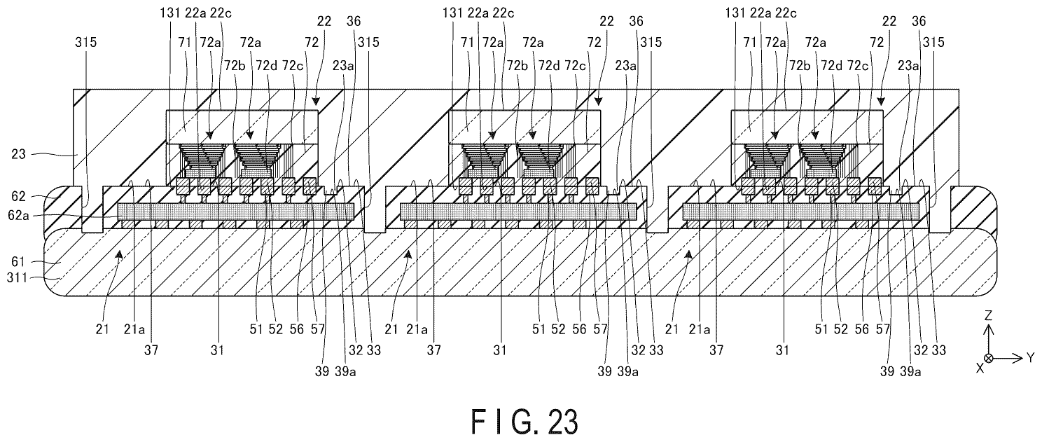

Next, as illustrated in FIG. 23, the sealing resin 23 is provided above the CMOS wafer 311. In this way, the first semiconductor chip 21, the second semiconductor chip 22, and the groove portion 315 are sealed with the sealing resin 23. Then, the sealing resin 23 enters the hole portion 39a, inner walls of which are the recess surfaces 39, forming the protruding portions 23a. This creates recesses and protrusions in a part of the interface 36 between the first semiconductor chip 21 and the sealing resin 23.

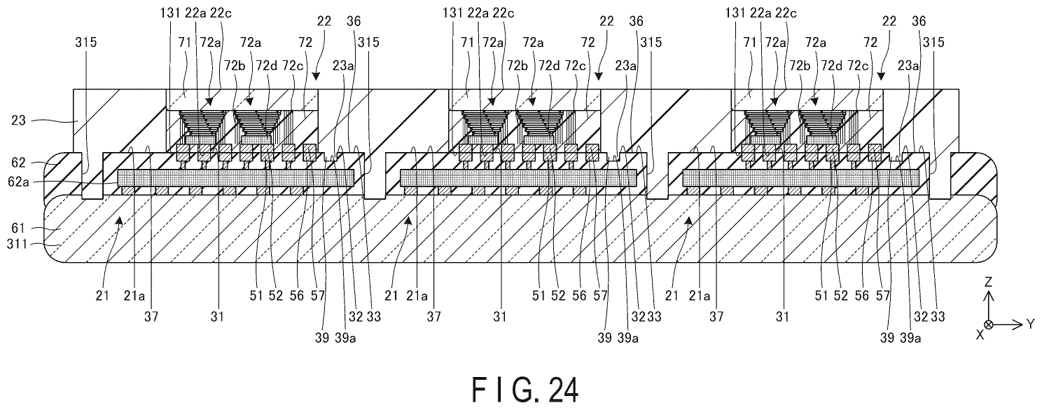

Next, as illustrated in FIG. 24, the upper surface of the sealing resin 23 is subjected to chemical mechanical polishing (CMP) so that the upper surfaces of the semiconductor layer 71, that is, the surfaces 22c of the second semiconductor chip 22 are exposed from the sealing resin 23. Then, the CMOS wafer 311 is subjected to degassing annealing.

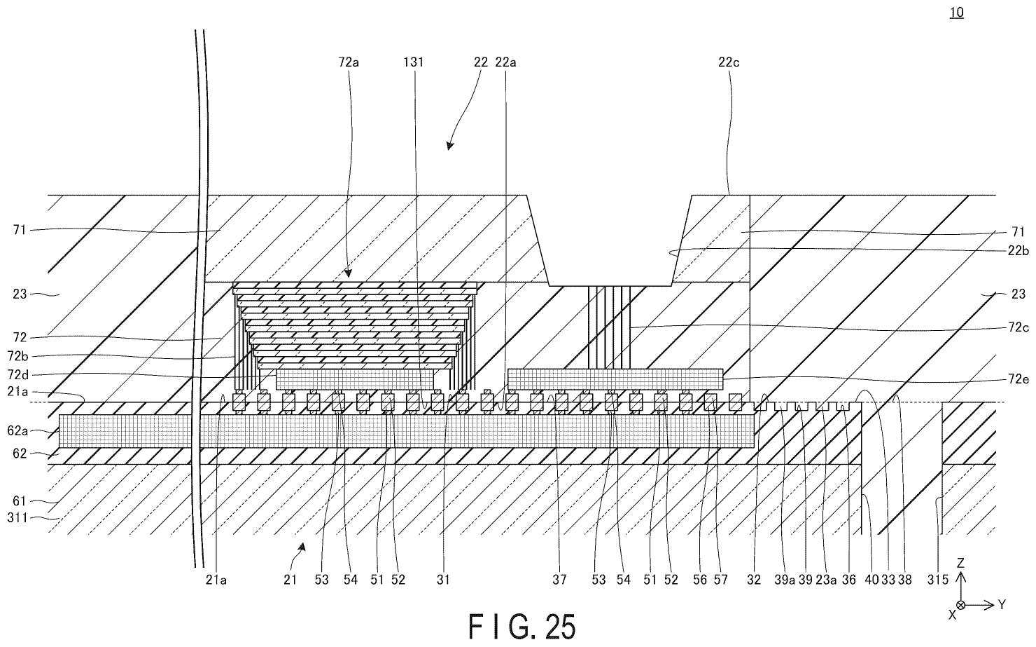

Next, as illustrated in FIG. 25, the surfaces 22c of the second semiconductor chip 22 are subjected to film forming, resist application, exposure, development, and stripping through a PEP (Photo Engraving Process) method, and thereafter, the hole portion 22b that passes through to the insulating layer 72 is formed in the semiconductor layer 71 by reactive ion etching (RIE).

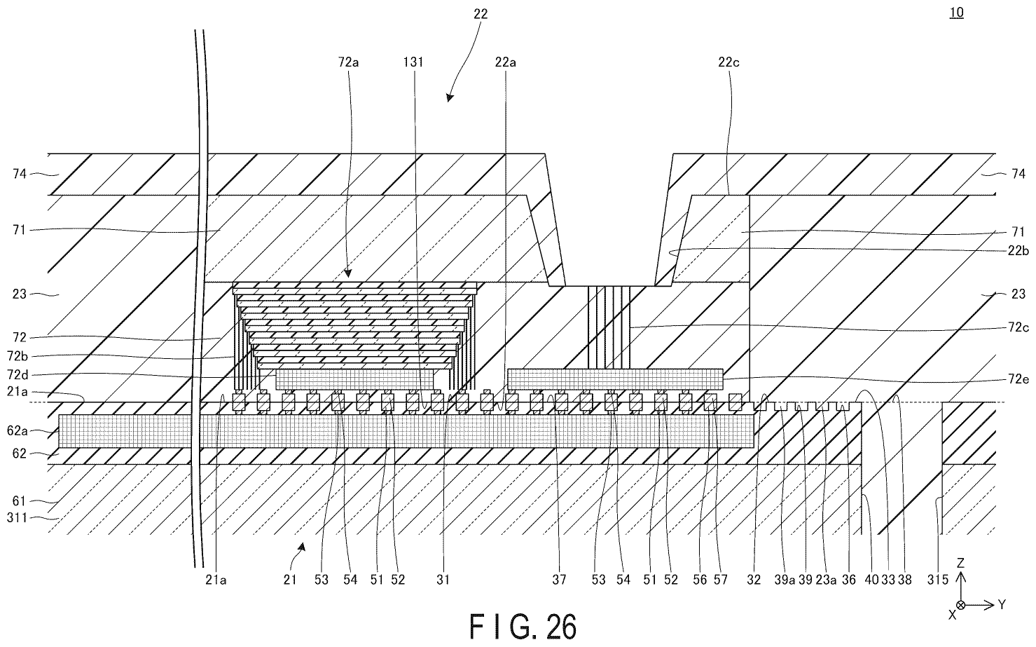

Next, as illustrated in FIG. 26, the surface 22c of the second semiconductor chip 22 is subjected to film forming, resist application, exposure, development, and stripping through a PEP method, and thereafter, the insulating layer 74 including, for example, polyimide is formed above the semiconductor layer 71.

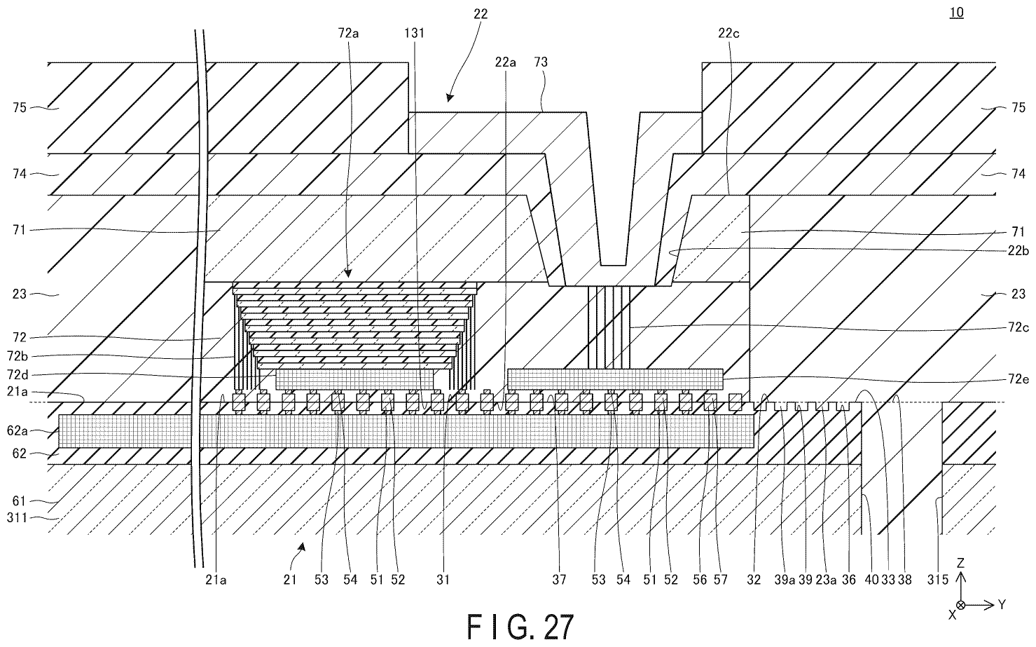

Next, as illustrated in FIG. 27, the upper surface of the insulating layer 74 is subjected to film forming, resist application, exposure, development, and stripping through a PEP method to form the insulating layer 75, which is a resist. Then, nickel and gold are deposited to form the bonding pad 73.

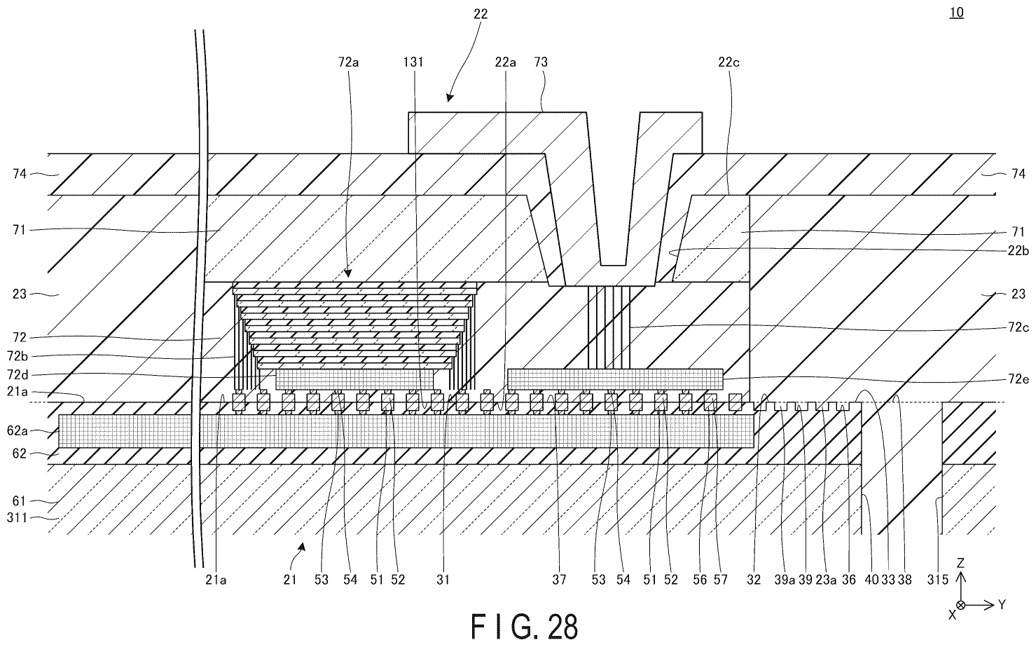

Next, as illustrated in FIG. 28, the insulating layer 75 is removed by, for example, etching.

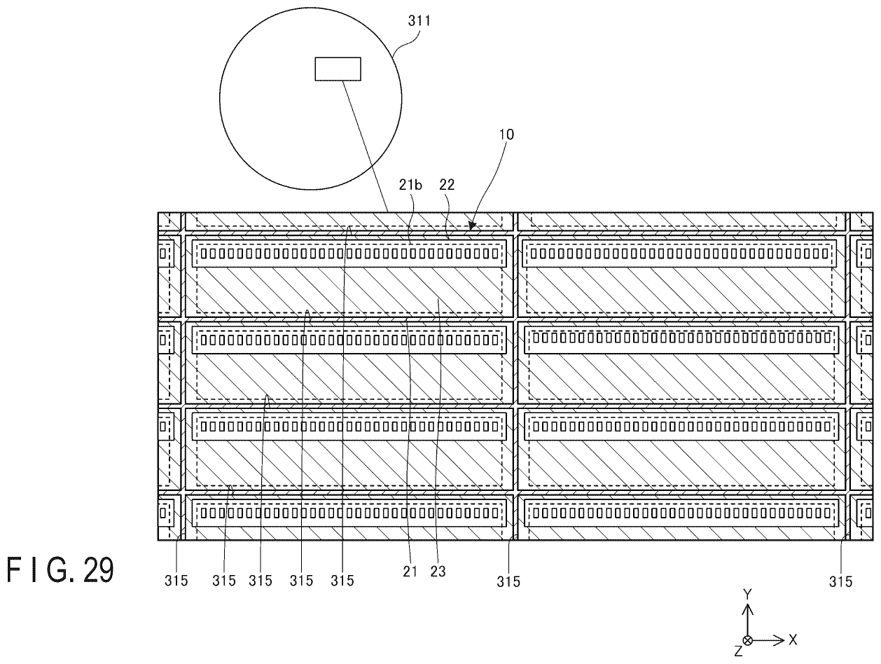

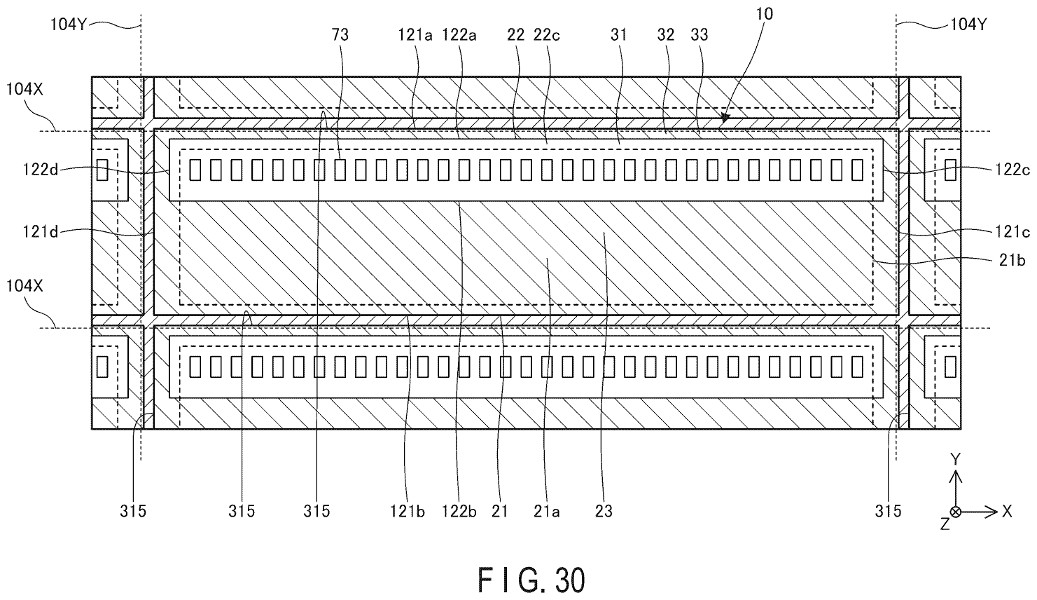

Next, as illustrated in FIGS. 29 and 30, the CMOS wafer 311 is subjected to dicing along dicing lines 104X and 104Y and thereby separated into a plurality of semiconductor devices 10 (see FIG. 30).

Specifically, there are a plurality of semiconductor devices 10 formed on the CMOS wafer 311 (see FIG. 29). For example, when viewed from above in plan view, the CMOS wafer 311 is subjected to dicing along the dicing line 104X extending substantially in parallel to the X-axis between the side 121a and the side 122a. The CMOS wafer 311 is also subjected to dicing, for example, along the dicing line 104Y extending substantially in parallel to the Y-axis between the side 121c and the side 122c.

In this way, as illustrated in FIG. 3, the semiconductor device 10 is produced, in which, in a cut surface after being diced, the side surface 40 in connection with the second region 32 on the side 121a of the surface 21a, that is, the surface of the CMOS wafer 311 in the Y-axis plus direction, and the surface of the insulating layer 62 in the Y-axis plus direction are exposed.

In an alternative configuration, the CMOS wafer 311 may be subjected to dicing along a dicing line substantially in parallel to the Y-axis between the side 121d and the side 122d.

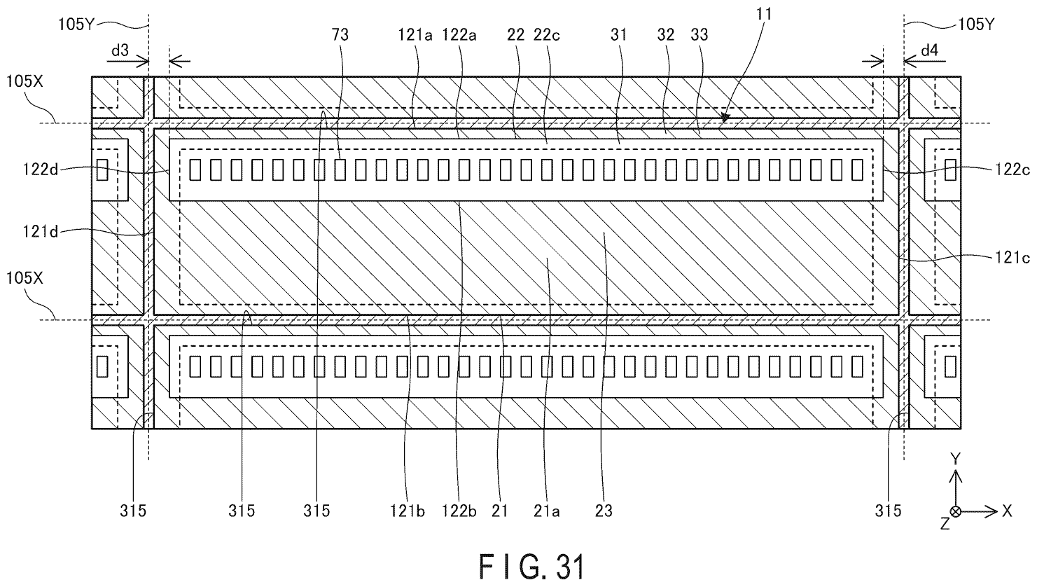

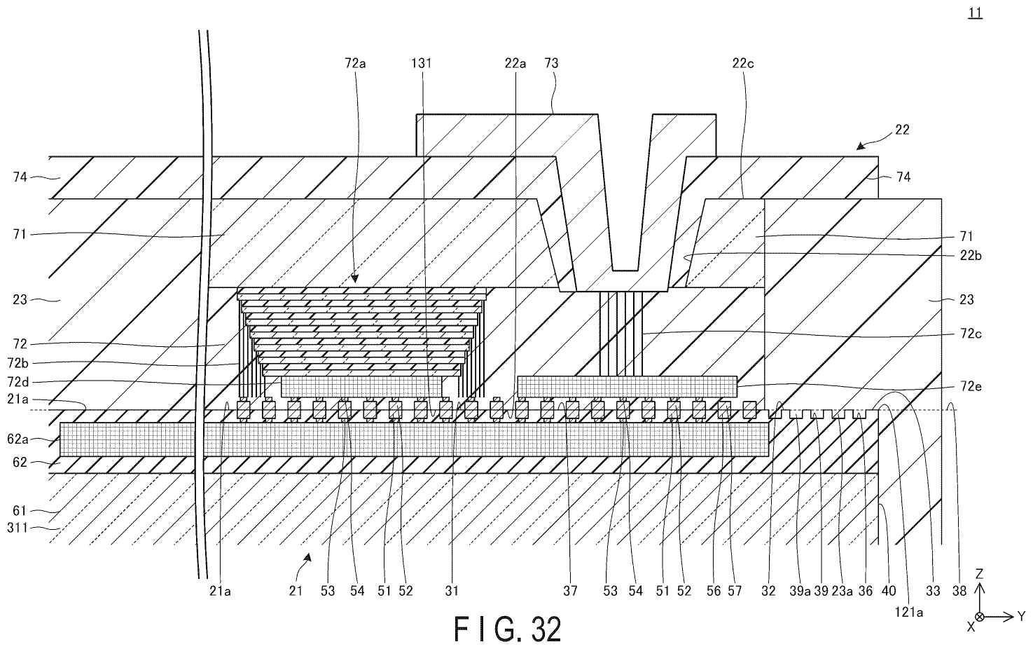

Furthermore, as illustrated in FIGS. 31 and 32, in an alternative configuration, the CMOS wafer 311 may be subjected to dicing along dicing lines 105X and 105Y that pass through substantially the centers of groove portions 315 and thereby separated into a plurality of semiconductor devices 11.

In this configuration, the sealing resin 23 is provided from the second region 32 through the side surface 40. Specifically, for example, the lower surface of the CMOS wafer 311 is polished so that the bottom below the groove portion 315 is removed.

In other words, the CMOS wafer 311 between two semiconductor devices 11 that are adjacent to each other is removed. This leaves only the sealing resin 23 provided between two semiconductor devices 11 that are adjacent to each other.

In this state, when dicing is performed along the dicing lines 105X and 105Y, the CMOS wafer 311 is not cut, but the sealing resin 23 is cut.

In this way, the semiconductor device 11 is produced, in which the side surface 40 is not exposed in a cut surface after being diced (see FIG. 32).

### Advantageous Effects

If the entirety of the upper surface 22c of the second semiconductor chip 22 is covered with the sealing resin 23, the sealing resin 23 in the third region 33 is supported from above by the sealing resin 23 that covers the surface 22c of the second semiconductor chip 22. Accordingly, the sealing resin 23 in the third region 33 is prevented from falling off.

On the other hand, when viewed from above in plan view, at least a part of the surface 22c of the second semiconductor chip 22 is exposed from the sealing resin 23, the sealing resin 23 in the third region 33 will be supported weakly from above. Accordingly, the sealing resin 23 may possibly fall off during dicing.

Furthermore, due to a low level of adhesion between the silicon included in the first semiconductor chip 21 and the sealing resin 23, the sealing resin 23 is more likely to fall off during dicing.

On the contrary, in the semiconductor devices 10 and 11 (see FIGS. 3 and 32), the interface 36 between the first semiconductor chip 21 and the sealing resin 23 have recesses and protrusions. Accordingly, the level of adhesion between the first semiconductor chip 21 and the sealing resin 23 can be enhanced, and it is thereby possible to prevent the sealing resin 23 from falling off during dicing.

### Second Embodiment

A semiconductor device 12 according to the second embodiment will be described. From the second embodiment, description of common matters with the first embodiment will not be repeated and only differences will be described. In particular, similar operation and effects produced by similar configurations will not be referred to every time in each embodiment.

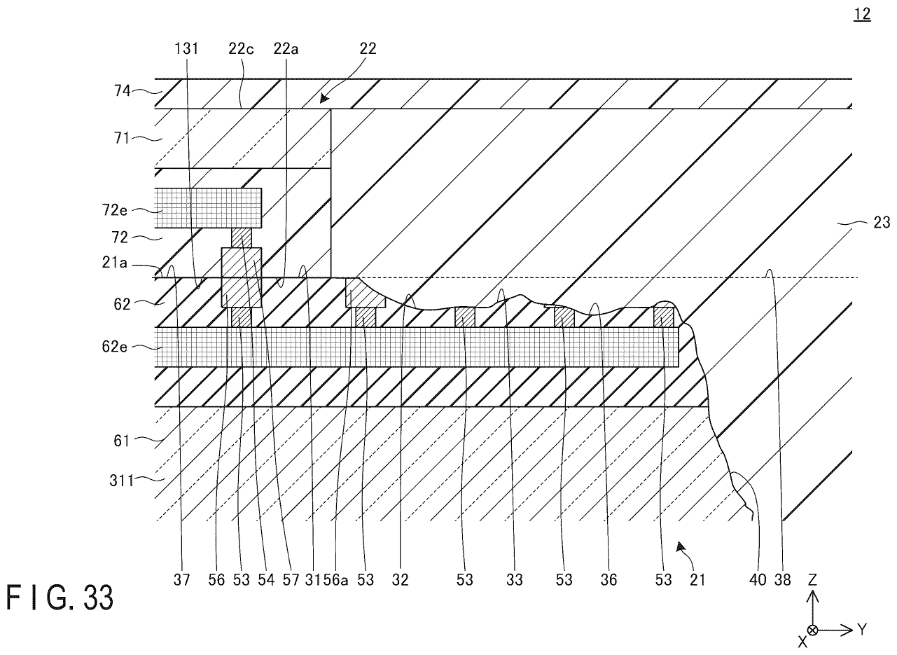

As illustrated in FIG. 33, in the semiconductor device 12, a part of the sealing resin 23 adjoins metal that has a same composition as the pads 51 and the dummy pads 56 at the interface 36 that has recesses and protrusions.

In the embodiment, the vias 53 are provided below the dummy pads 56a. At the interface 36 that has recesses and protrusions, the dummy pads 56a and the vias 53 are exposed from the insulating layer 62. The dummy pads 56a and the vias 53 exposed from the insulating layer 62 adjoin the sealing resin 23.

### [Manufacturing Method of Semiconductor Device]

In a manufacturing method of the semiconductor device 12, in place of the step in which the dummy pads 56a in the CMOS wafer 311 are removed by being subjected to wet etching (see FIG. 22), the step in which the groove portions 315 are formed by laser grooving process (see FIG. 20) is followed by a step in which recesses and protrusions are formed in the third region 33 by laser.

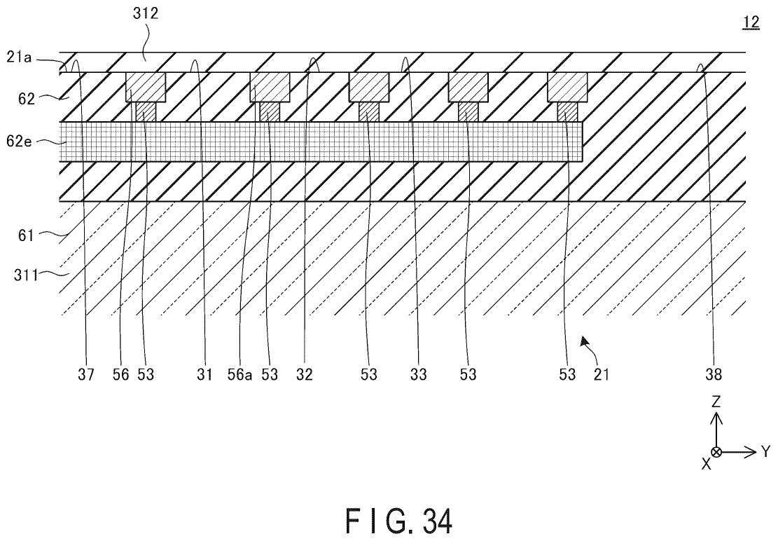

To be specific, as illustrated in FIG. 34, the protective film 312 is formed on the upper surface of the insulating layer 62.

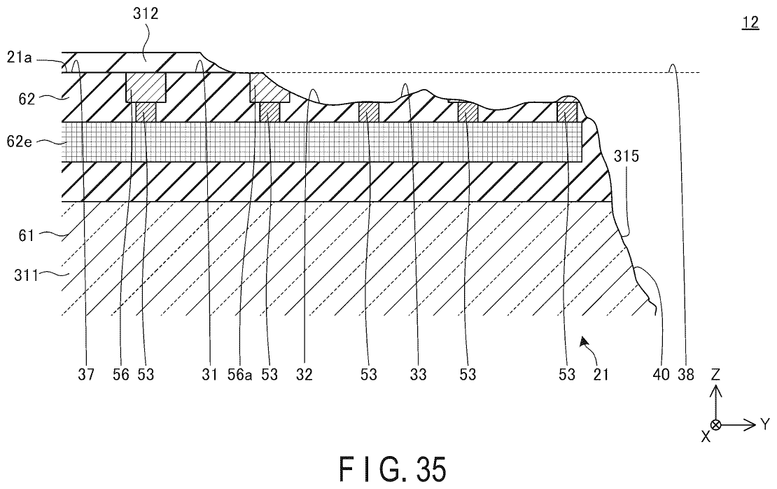

Next, as illustrated in FIG. 35, in the CMOS wafer 311, the groove portion 315 is formed with the upper surface being irradiated with laser. Those components formed on the CMOS wafer 311 are divided into the first semiconductor chips 21 across the groove portion 315. Then, for example, the third region 33 is irradiated with lower-powered laser, so that the protective film 312, the insulating layer 62, the dummy pads 56, and the vias 53 are scraped off.

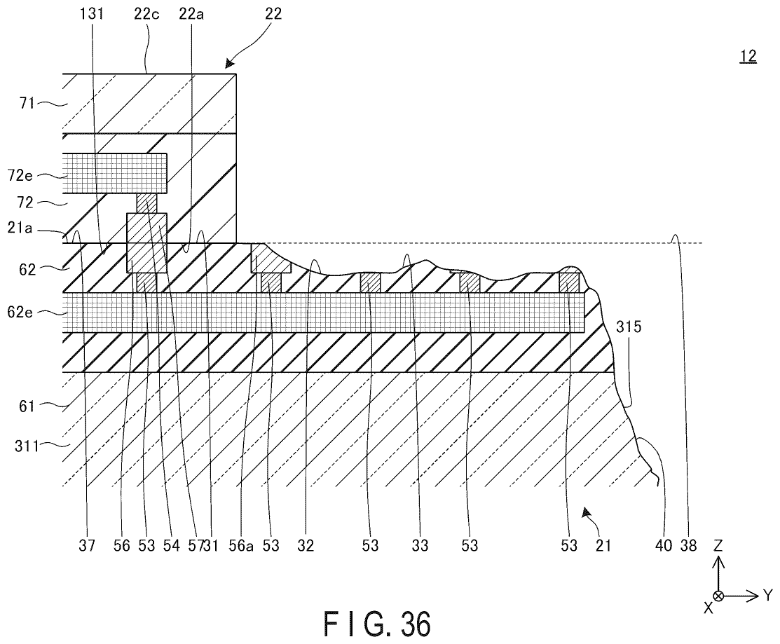

Next, as illustrated in FIG. 36, the protective film 312 is removed. As a preprocessing for processing of bonding the second semiconductor chip 22 to the first semiconductor chip 21, the CMOS wafer 311 is subjected to nitrogen plasma processing and rinsing. Then, the second semiconductor chip 22 is bonded to the first semiconductor chip 21. At this time, among a plurality of dummy pads 56, the dummy pads 56a and the vias 53, a part of which is scraped off by laser, are exposed from the insulating layer 62. Thereafter, the CMOS wafer 311 is annealed.

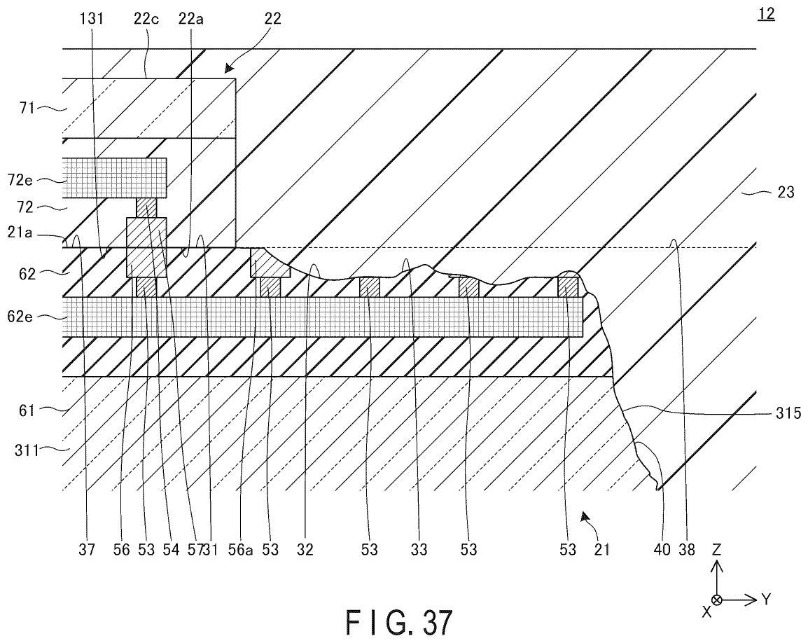

Next, as illustrated in FIG. 37, the sealing resin 23 is provided above the CMOS wafer 311. In this way, the first semiconductor chip 21, the second semiconductor chip 22, and the groove portion 315 are sealed with the sealing resin 23. In the third region 33, this creates recesses and protrusions in the interface 36 between the sealing resin 23 and the first semiconductor chip 21.

### Third Embodiment

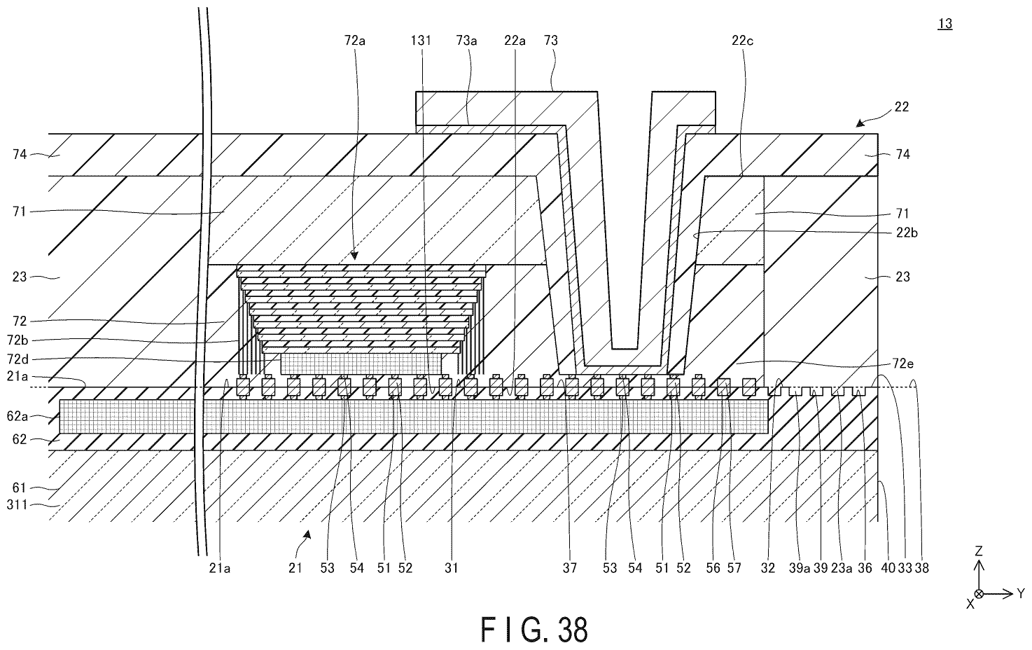

The semiconductor device 13 according to the third embodiment will be described. FIG. 38 is a sectional view of the semiconductor device according to the third embodiment. FIG. 38 should be examined similarly as in FIG. 3.

As illustrated in FIG. 38, as compared to the semiconductor device 10 illustrated in FIGS. 2 and 3, the semiconductor device 13 is different from the semiconductor device 10 according to the first embodiment in that the hole portion 22b passes through the semiconductor layer 71 and the insulating layer 72, and a barrier metal 73a is provided below the bonding pad 73. The barrier metal 73a includes, for example, titanium or titanium and nitrogen.

In an alternative configuration, the hole portions 22b in the semiconductor devices 11 and 12, which are illustrated in FIG. 33 and FIG. 34, respectively, may each pass through the semiconductor layer 71 and the insulating layer 72 as with the semiconductor device 13.

### Fourth Embodiment

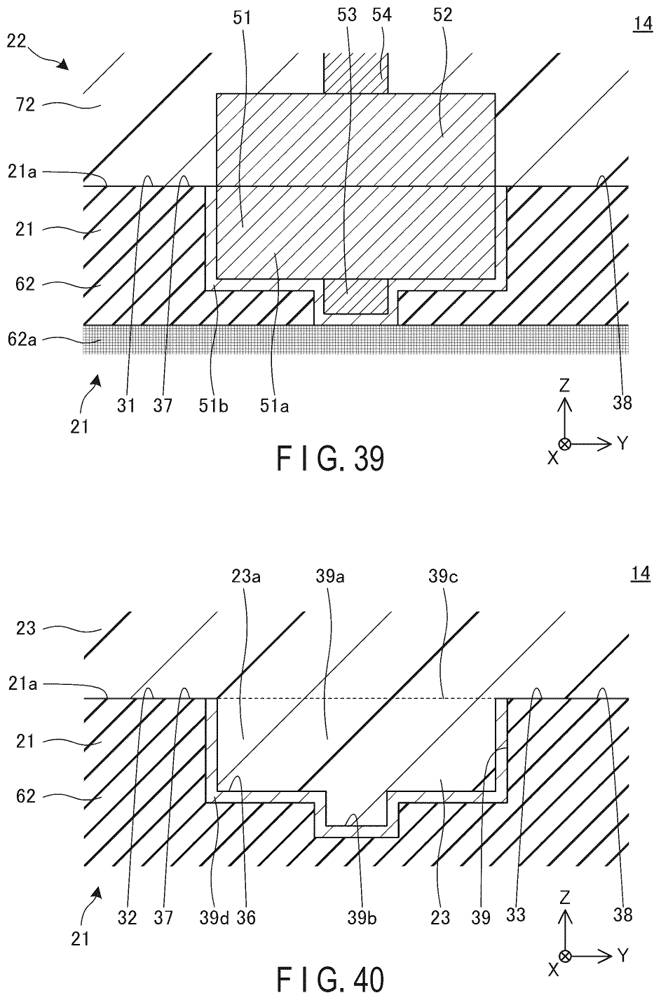

The semiconductor device according to the fourth embodiment will be described. FIG. 39 is a sectional view of a pad and a via according to the fourth embodiment.

As illustrated in FIG. 39, the pad 51 includes a metal layer 51a (an example of “first metal layer”) and a metal layer 51b (an example of “second metal layer”) provided between the metal layer 51a and the insulating layer 62.

In the embodiment, the metal layer 51b is provided between the pad 51/the via 53 and the insulating layer 62. In an alternative configuration, the via 53 may not be provided.

Although not illustrated, the dummy pad 56 and the dummy pad 56a also have similar configurations to the pad 51.

Through a process in which the via 53 below the dummy pad 56a is removed along with the dummy pad 56a by wet etching (see FIG. 22), as illustrated in FIG. 40, a metal layer 39d (an example of “third metal layer”) that has a same composition and a shape as the metal layer 51b is exposed in the recess surface 39.

Next, the sealing resin 23 is provided above the CMOS wafer 311. Specifically, the sealing resin 23 enters the hole portion 39a, inner walls of which are the metal layer 39d, forming the protruding portion 23a.

After removing the dummy pad 56a and the via 53 located below, wet etching is performed to remove the barrier metal 52a, so that the hole portion 39a from which the metal layer 39d has been removed is formed (see FIG. 5).

(a) In the embodiments, although description has been made as to configurations in which the interface 36 in the third region 33 has recesses and protrusions, this is not a limitation. In an alternative configuration, the interface 36 in a part or all of the second region 32 may have recesses and protrusions. To be specific, in an alternative configuration, the interface 36 between the side 121c of the first semiconductor chip 21 and the second semiconductor chip 22, as well as between the side 121d of the first semiconductor chip 21 and the second semiconductor chip 22 may have recesses and protrusions. Furthermore, in an alternative configuration, the interface 36 between the side 121b of the first semiconductor chip 21 and the second semiconductor chip 22 may have recesses and protrusions.

(b) In the embodiments, although description has been made as to configurations in which the pad 51/the dummy pad 56 and the pad 52/the dummy pad 57 are joined, respectively, so that the first semiconductor chip 21 and the second semiconductor chip 22 are bonded, this is not a limitation. In an alternative configuration, for example, the first semiconductor chip 21 and the second semiconductor chip 22 may be adhered with resin such as a die-attach film.

(c) In the embodiments, as illustrated in FIG. 4 for example, although description has been made as to configurations in which the protruding portion 23a of the sealing resin 23 completely enters the hole portion 39a, this is not a limitation. Any void may be formed partially between the sealing resin 23 and the recess surfaces 39. Even in such a case, in a portion in which the sealing resin 23 and the recess surfaces 39 are in close contact with each other, that is, a portion in which no void is formed, the interface 36 with recesses and protrusions between the sealing resin 23 and the first semiconductor chip 21 is formed. Accordingly, it is possible to ensure a level of adhesion between the first semiconductor chip 21 and the sealing resin 23, and it is therefore possible to prevent the sealing resin 23 from falling off during dicing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first semiconductor chip that has a first surface including a first region and a second region adjacent to the first region;
a second semiconductor chip provided on the first region; and
resin provided on the second region and adjoining the second semiconductor chip, wherein
at least a part of an interface between the first semiconductor chip and the resin has recesses and protrusions.

2. The semiconductor device of claim 1, wherein
the second semiconductor chip is bonded to the first region of the first surface of the first semiconductor chip,
the second region of the first surface of the first semiconductor chip includes recesses at a bonding plane between the first semiconductor chip and the second semiconductor chip, and
the resin has a protruding portion that occupies at least a part of the recesses.

3. The semiconductor device of claim 2, further comprising:
a first pad on the first surface of the first semiconductor chip,
a second pad on the second semiconductor chip, the first pad and the second pad are joined so as to bond the first semiconductor chip and the second semiconductor chip,
a shape of section perpendicular to the first pad is the same as a shape of section perpendicular to the protruding portion.

4. The semiconductor device of claim 1, wherein
the first semiconductor chip has a first side and a second side that are opposite to each other when the first surface is viewed in plan view along a direction perpendicular to the first surface,
the first region is located nearer to the first side than the second side,
the second region includes a third region located between the first side and the first region, and
the interface in at least a part of the third region includes the recesses and protrusions.

5. The semiconductor device of claim 1, wherein
the first semiconductor chip has a side surface in connection with the second region at a side of the first surface, and
the resin is provided from the second region through the side surface.

6. The semiconductor device of claim 1, wherein
the second region of the first semiconductor chip includes recesses at a bonding plane between the first semiconductor chip and the second semiconductor chip, and
the recesses have a geometrical pattern when the first surface of the first semiconductor chip is viewed in plan view along a direction perpendicular to the first surface.

7. The semiconductor device of claim 1, wherein
the second region of the first semiconductor chip includes recesses at a bonding plane between the first semiconductor chip and the second semiconductor chip, and
the recesses include a rectangular, circular, or elliptical outline when the first surface of the first semiconductor chip is viewed in plan view along a direction perpendicular to the first surface.

8. The semiconductor device of claim 1, wherein
the second region of the first semiconductor chip includes recesses at a bonding plane between the first semiconductor chip and the second semiconductor chip, and
a shape of an opening of the recesses is larger than a shape of a bottom of the recesses.

9. The semiconductor device of claim 1, wherein
the second region of the first semiconductor chip includes recesses at a bonding plane between the first semiconductor chip and the second semiconductor chip, and
a shape of an opening of the recesses and a shape of a bottom of the recesses are substantially same.

10. The semiconductor device of claim 1, further comprising:
a first pad on the first surface of the first semiconductor chip,
a second pad on the second semiconductor chip,
the first pad and the second pad are joined so as to bond the first semiconductor chip and the second semiconductor chip, and
a part of the resin adjoins a metal that has a same composition as the first pad at the interface that has the recesses and protrusions.

11. The semiconductor device of claim 1, wherein
an insulating layer and a first pad exposed from the insulating layer are formed in the first region of the first semiconductor chip,
a second pad is formed in the second semiconductor chip,
the first pad and the second pad are joined so as to bond that the first semiconductor chip and the second semiconductor chip,
the second region includes recesses at bonding plane between the first semiconductor chip and the second semiconductor chip,
the first pad includes a first metal layer and a second metal layer provided between the first metal layer and the insulating layer, and
a third metal layer that has a same composition as the second metal layer is exposed in surfaces of the recesses.

12. The semiconductor device of claim 1, wherein
the first semiconductor chip includes silicon.

13. The semiconductor device of claim 1, wherein
the second semiconductor chip includes a plurality of stacked memory chips.

14. The semiconductor device of claim 1, wherein
at least a part of a top surface of the second semiconductor chip is exposed from the resin when the first surface is viewed in plan view along a direction perpendicular to the first surface.

15. A method of manufacturing a semiconductor device, the method comprising:
providing a first chip on a first region of a wafer;
forming a recess on a second region of the wafer which is different from the first region;
providing a resin so as to cover the second region; and
cutting around the second region of the wafer.

16. The method of claim 15, further comprising:
forming a first pad in the first region and a second pad in the second region; and
forming a third pad in a surface of the first chip, wherein
providing the first chip on the first region of the wafer includes directly bonding the third pad to the first pad, and
forming the recess includes etching the second pad.

17. The method of claim 16, wherein
the first pad and the second pad are formed simultaneously.

18. The method of claim 15, further comprising:
polishing a surface of the resin after the resin has been provided; and
forming a fourth pad on a surface of the first chip opposite to the wafer after polishing the surface of the resin.

19. The method of claim 15, further comprising:
graving around the second region of the wafer before providing the resin.

20. The method of claim 16, wherein
a CMOS circuit electrically connected to the first pad is provided in the wafer, and
a memory circuit electrically connected to the second pad is provided in the first chip.
